(19) United States
(12) Patent Application Publication
(10) Pub. No.: US 2025/0003904 A1
(43) Pub. Date: Jan. 2, 2025

(54) DETECTING HUMIDITY BY MEASURING IMPEDANCE BETWEEN TWO TRACKS

(71) Applicant: SAGEMCOM ENERGY & TELECOM SAS, BOIS-COLOMBES (FR)

(72) Inventors: Abbas SABRAOUI, BOIS-COLOMBES (FR); Patrick WEBER, BOIS-COLOMBES (FR)

(21) Appl. No.: 18/760,509

(22) Filed: Jul. 1, 2024

(30) Foreign Application Priority Data
Jun. 30, 2023 (FR) FR2306944

(51) Int. Cl. G01N 27/02; H05K 1/02

(52) U.S. Cl. CPC G01N 27/02; H05K 1/0266

(57) ABSTRACT

A device for monitoring humidity on or in a printed circuit includes a first track and a second track printed on the printed circuit, and not connected to one another, a test device arranged to apply a test voltage on one of the first track and second track, the other track being connected to a constant or controlled voltage reference, compare a target voltage, representative of an impedance between the first conductive track and the second conductive track, with a predetermined threshold, and detect a humidity level which is too high according to a result of said comparison.

The invention relates to the field of detecting humidity on electronic boards.

### BACKGROUND OF THE INVENTION

There is a certain number of reasons which are able to cause a humidity level which is too high on an electronic board.

One of these reasons is as follows. In the case of a coated or overmoulded electronic board, when the resin is not correctly debubbled (process necessary for removing all the air bubbles before polymerisation), the bubbles can remain blocked near the electronic components of the board. Temperature variations can thus cause condensation, leading to a significant risk of short-circuiting and of corrosion.

It is known, to evaluate the humidity level on a board, to use a humidity sensor. Thus, an integrated capacitive sensor in a SMC (surface-mounted component) box is frequently used to measure humidity.

This type of sensor poses the following problem. The performance of the sensor is limited, when it is welded on an electronic board covered with resin (like a flexible resin) or mask, as resin or mask obstructs the sensor and reduces the reliability of the measurements.

Moreover, the electric consumption of this type of sensor is relatively high, which can be a disadvantage for certain applications. In fluid meters, for example (water, gas, etc.), the electronic functions are generally powered by a cell or a battery, and it is therefore crucial to limit the consumption of said functions to the maximum.

### AIM OF THE INVENTION

The invention aims to improve the effectiveness of detecting humidity on or in a printed circuit, while reducing the electric consumption required by this detection.

### SUMMARY OF THE INVENTION

In view of achieving this aim, a device for monitoring humidity on or in a printed circuit is proposed, comprising:
a first conductive track and a second conductive track printed on the printed circuit, and not connected to one another;
a test device, arranged to:
   apply a test voltage on one of the first conductive track and second conductive track, the other of the first conductive track and second conductive track being connected to a constant or controlled voltage reference;
   compare a target voltage, representative of an impedance between the first conductive track and the second conductive track, with a predetermined threshold, said impedance being reduced in the presence of humidity;
   detect a humidity level which is too high on or in the printed circuit, between the first conductive track and the second conductive track, according to a result of said comparison.

The monitoring device is capable of detecting the presence of humidity on or in the printed circuit, even when this is covered with resin or with mask.

The monitoring device is extremely simple to produce and very inexpensive, since these are conductive tracks printed on the printed circuit which act as a sensor. The electric consumption of the monitoring device is very low.

In addition, a monitoring device such as described above is proposed, wherein the test voltage is a direct voltage.

In addition, a monitoring device such as described above is proposed, wherein the first conductive track comprises a first track portion, which is not covered with solder mask, and wherein the second conductive track comprises a second track portion, which is not covered with solder mask.

In addition, a monitoring device such as described above is proposed, wherein the first track portion extends over a first segment of the first conductive track, and the second track portion extends over a second segment of the second conductive track, the first segment and the second segment going along, over the printed circuit, being substantially parallel and being substantially of the same length.

In addition, a monitoring device such as described above is proposed, wherein the first track portion and the second track portion are covered with a protective coating intended to prevent a main material, with which the first conductive track and the second conductive track are manufactured, from corroding.

In addition, a monitoring device such as described above is proposed, the protective coating being made of gold-nickel.

In addition, a monitoring device such as described above is proposed, wherein the first conductive track and the second conductive track form two loop-shaped electrodes.

In addition, a monitoring device such as described above is proposed, wherein the first conductive track and the second conductive track form two interdigitated electrodes.

In addition, a monitoring device such as described above is proposed, wherein:
the first conductive track is connected to at least one first castellation formed in a thickness of the printed circuit, and
the second conductive track is connected to at least one second castellation formed in the thickness of the printed circuit,
the test voltage being applied on the first conductive track and the target voltage being measured on the second conductive track.

In addition, a monitoring device such as described above is proposed, wherein the first conductive track comprises two first sections connected to one another, perpendicular to one another and each connecting two first castellations to one another, and the second conductive track comprises two second sections connected to one another, perpendicular to one another and each connecting two second castellations to one another.

In addition, a monitoring device such as described above is proposed, wherein the first conductive track and the second conductive track are located on one same layer of the printed circuit.

In addition, a monitoring device such as described above is proposed, wherein said layer is an internal layer of the printed circuit.

In addition, a monitoring device such as described above is proposed, comprising a first conductive track and a second conductive track located on a first layer of the printed circuit, and another first conductive track and another second conductive track located on a second layer of the printed circuit, the first conductive tracks being connected to one another by at least one first through via and the second conductive tracks being connected to one another by at least one second through via.

In addition, a monitoring device such as described above is proposed, comprising several first conductive tracks connected in series and several second conductive tracks connected in series.

In addition, a monitoring device such as described above is proposed, comprising several first conductive tracks connected in parallel and several second conductive tracks connected in parallel.

In addition, a monitoring device such as described above is proposed, wherein the first conductive track and/or the second conductive track are also used to transport signals used for another function, detecting the humidity level which is too high being done by the monitoring device, when said other function is inactive.

In addition, a monitoring device such as described above is proposed, wherein electric components are mounted on the printed circuit, these electric components comprising a component which is the most sensitive to humidity, the component which is the most sensitive to humidity being positioned in a zone surrounded by the first conductive track and the second conductive track.

In addition, a monitoring device such as described above is proposed, comprising an analogue comparator and a voltage source, the target voltage being compared by the analogue comparator with a reference voltage produced by the voltage source, the predetermined threshold thus being an analogue threshold.

In addition, a detection method is proposed, implemented in a monitoring device such as described above, comprising the steps of:
applying a test voltage on one of the first conductive track and second conductive track, the other of the first conductive track and second conductive track being connected to a constant or controlled voltage reference;
comparing a target voltage, representative of an impedance between the first conductive track and the second conductive track, with a predetermined threshold, said impedance being reduced in the presence of humidity;
detecting a humidity level which is too high on or in the printed circuit, between the first conductive track and the second conductive track, according to a result of said comparison.

In addition, a computer program comprising instructions which cause the test device of the monitoring device such as described above to execute the steps of the detection method such as described above is proposed.

In addition, a recording medium which can be read by a computer, on which the computer program such as described above is recorded, is proposed.

The invention will be best understood in the light of the description below of particular, non-limiting embodiments of the invention.

### BRIEF DESCRIPTION OF THE DRAWINGS

Reference will be made to the accompanying drawings, among which:

FIG. 1 FIG. 1 is a cross-sectional view of a printed circuit portion according to a first embodiment, along a plane perpendicular to said printed circuit;

FIG. 2 FIG. 2 represents the first conductive track and the second conductive track forming loop-shaped electrodes, as well as a test device according to a first embodiment;

FIG. 3 FIG. 3 represents the first track and the second track forming interdigitated electrodes;

FIG. 4 FIG. 4 represents the first conductive track and the second conductive track forming electrodes according to a castellation configuration;

FIG. 5 FIG. 5 represents the first conductive track and the second conductive track forming loop-shaped electrodes, as well as a test device according to a second embodiment;

FIG. 6 FIG. 6 represents the first conductive track and the second conductive track forming loop-shaped electrodes, as well as a test device according to a third embodiment;

FIG. 7 FIG. 7 represents the first conductive track and the second conductive track forming loop-shaped electrodes, as well as a test device according to a fourth embodiment;

FIG. 8 FIG. 8 represents the steps of a detection method;

FIG. 9 FIG. 9 is a cross-sectional view of a printed circuit portion according to a second embodiment, along a plane perpendicular to said printed circuit.

### DETAILED DESCRIPTION OF THE INVENTION

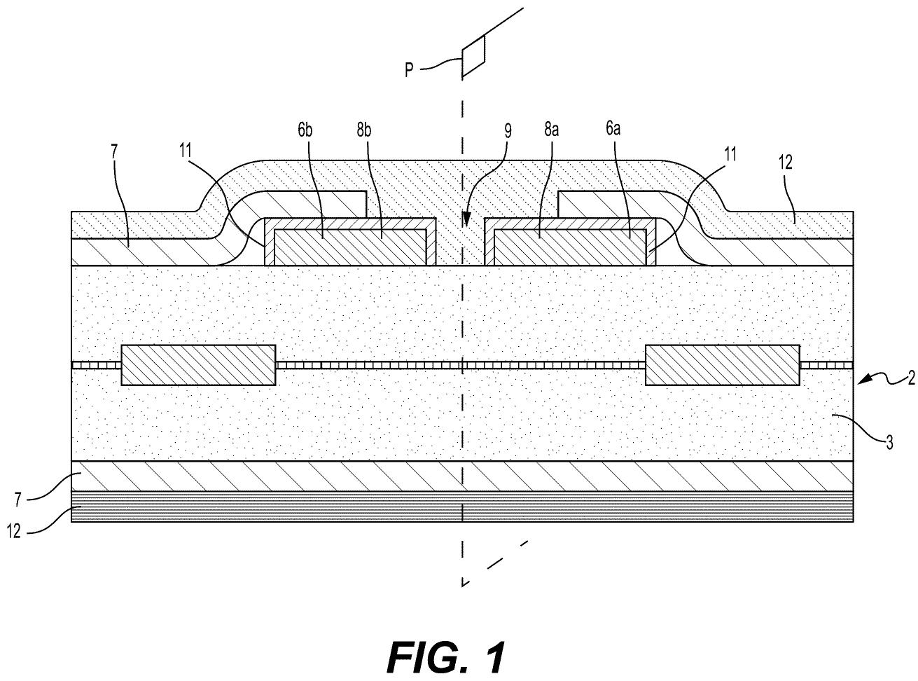

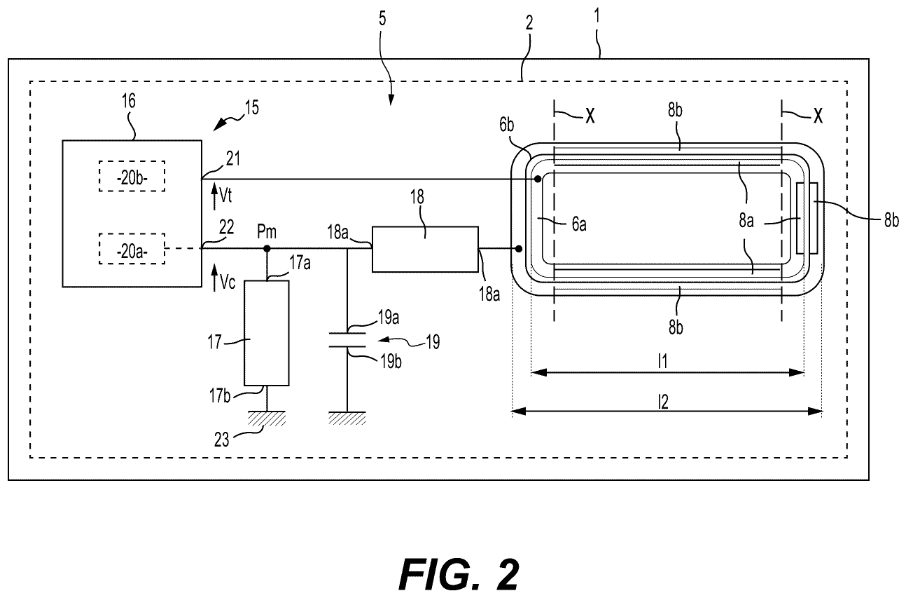

In reference to FIGS. 1 and 2, a water meter 1 comprises an electronic board 2 comprising a printed circuit 3 on which electronic components are mounted.

The electronic components comprise components performing one or more various functions implemented in a water meter: metrology (measuring water consumption), communication (transmitting consumption measurements, interface with the user), monitoring (detecting a leak, meter malfunction, fraud attempt), electrical powering of the components of the electronic board functions, etc.

The water meter 1 comprises a monitoring device 5 of the humidity level on or in the printed circuit 3.

The monitoring device 5 comprises a first conductive track 6a (copper, for example) and a second conductive track 6b (copper, for example) printed, in this case, on one same layer (upper layer) or the printed circuit 3. The first track 6a and the second track 6b are not connected to one another.

The first track 6a and the second track 6b form two electrodes, in this case, each loop-shaped. The first electrode therefore forms a first loop and the second electrode forms a second loop. Each loop has the shape of a rectangle with rounded corners.

The first track 6a and the second track 6b are disposed such that the second track 6b surrounds the first track 6a.

The first track 6a is therefore located inside the second loop formed by the second track 6b.

The first track 6a and the second track 6b have the same shape, but the dimensions of the second track 6a are slightly less than those of the first track 6b. The second track 6b goes along the first track 6a over all of their length.

The first track 6a and the second track 6b are very close: each point of the first track 6a is located at a distance from a point closest to the second track 6b, which is between 1% and 10% of a greater dimension of the shape of the first electrode and/or of the second electrode.

In this case, the greatest dimension of the first electrode is the length L1, and the greatest dimension of the second electrode is the length L2.

The printed circuit 1 is covered with solder mask 7 over a large part of its external layers (upper and lower).

The first track 6a comprises (at least) one first track portion 8a, which is not covered with solder mask, and the second track 6b comprises (at least) one second track portion 8b, which is not covered with solder mask.

In this case, the first track 6a comprises three first track portions 8a not covered with solder mask and the second track 6b comprises three second track portions 8b not covered with solder mask.

For the first track 6a, the first track portions 8a are located on a first side (length) of the first loop, on a second side (width) of the first loop, and on a third side (length) of the first loop.

Likewise, for the second track 6b, the second track portions 8b are located on a first side (length) of the second loop, on a second side (width) of the second loop, and on a third side (length) of the second loop.

Each first track portion 8a is associated with a second track portion 8b. The first track portion 8a extends over a first segment of the first track 6a. The second track portion 8b extends over a second segment of the second track 6b.

The first segment and the second segment going along over the printed circuit 3, are substantially parallel (i.e. that they extend substantially in one same direction without electrical contact), have substantially the same length (optionally with a small difference, of around 1 mm, for example), and have their ends substantially aligned along axes X perpendicular to said segments (optionally with a small gap, of around 1 mm, for example).

The first track portions 8a and the second track portions 8b are defined in zones, wherein the first track 6a and the second track 6b have dimensions which are fully controlled in manufacture.

Each first track portion 8a is therefore defined on a first segment of the first track 6a. The first track portion 8a is defined over the entire length and on an internal part of the width of the first segment. Likewise, each second track portion 8b is defined on a second segment of the second track 6b. The second track portion 8b is defined over the entire length and on an internal part of the width of the second segment.

By “internal”, this means the side of a plane P (which can be seen in FIG. 1) perpendicular to the printed circuit 1, located between the first track portion 8a and the associated second track portion 8b and parallel to these; the first track portion 8a and the second track portion 8b are therefore disposed facing one another and symmetrically with respect to the plane P.

The surface 9 of the printed circuit 1 located between each first track portion 8a and the associated second track portion 8b is not covered with solder mask either.

However, all of the surface of each of the first track portion 8a and second track portion 8b is, in this case, covered by a protective coating 11, which is preferably made of gold-nickel.

The coating is intended to prevent a main material, with which the first track 6a and the second track 6b are manufactured, from corroding.

The side edges of each of the first track portions 8a and second track portions 8b are also covered with this protective coating 11.

In addition, it is noted, that in this case, all of the printed circuit 1 is covered with a resin 12 (which therefore also covers the first and second track portions 8a, 8b, not covered with solder mask).

The monitoring device 5 in addition comprises a test device 15.

In this case, the test device 15 comprises electronic components which are mounted on the printed circuit 1 (but they could be positioned on another board).

The test device 15:
applies a test voltage Vt on the first track 6a (optionally via one or more components), the second track 6b being connected to a constant or controlled voltage reference;
compares a target voltage Vc, representative of an impedance between the first track 6a and the second track 6b, with a predetermined threshold, said impedance being reduced in the presence of humidity;
detects a humidity level which is too high on or in the printed circuit 1, between the first track 6a and the second track 6a, according to a result of said comparison.

The constant or controlled voltage reference, to which the second track is connected, is, in this case, an electrical ground 23. The second track is connected to this electrical ground 23 via passive components (17, 18, 19) described below.

The test voltage Vt is, in this case, a direct voltage and the impedance is a direct current impedance. The impedance between the first track 6a and the second track 6b depends on the current leaks due to the presence of humidity.

The test device 15 comprises, in this case, a microcontroller 16, a resistor 17, an inductor 18 and a capacitor 19.

The microcontroller 16 integrates an analogue-to-digital converter (ADC) 20a. The test device 15 also comprises one or more memories 20b, connected to or integrated in the microcontroller 16. At least one of these memories 20b forms a recording medium which can be read by a computer, on which at least one computer program comprising instructions which cause the microcontroller 16 to execute at least some of the steps of the detection method which will be described below, is recorded.

The microcontroller 16 has an output 21 (CTRL output), and an input 22 which is connected to its ADC 20a.

The output 21 is connected to the first track 6a directly. The input 22 is connected to the second track 6b via the resistor 17, the inductor 18 and the capacitor 19. The inductor 18 could itself be replaced by a resistor.

The resistor 17 has a terminal 17a connected to the input 22 and a terminal 17b connected to the electrical ground 23 of the electronic board 2.

The resistor 17 has a good robustness to humidity and has a high resistance value, for example, equal to 10 MΩ.

The capacitor 19 itself also has a terminal 19a connected to the input 22 and a terminal 19b connected to the electrical ground 23.

The capacitor 19 and the resistor 17 are therefore mounted in parallel.

The capacitor 19 is optional. The capacitor 19 is, for example, a ceramic capacitor, which has a good robustness to humidity. The capacitor 19 has, for example, a capacity value equal to 100 nF.

The inductor (or the resistor) 18 has a terminal 18a connected to the input 22, to the terminal 17a of the resistor 17 and to the terminal 19a of the capacitor 19, and a terminal 18b connected to the second track 6b.

The inductor (or the resistor) 18 is optional. The inductor (or the resistor) 18 is, for example, a multilayer inductor, which has a good robustness to humidity. The inductor 18 has, for example, an inductance value equal to 22 nH.

To detect humidity, the microcontroller 16 biases the first electrode by applying, on the first track 6a, the test voltage Vt, which is, in this case, a direct voltage equal to 3.3V (which is also the supply voltage Vcc of the microcontroller 16).

The ADC 20a thus digitises the target voltage Vc present at the input 22 of the microcontroller 16, which depends on the impedance between the first track 6a and the second track 6b. The target voltage Vc is measured at a measuring point connected to the second track 6b via the inductor (or the resistor) 18, the resistor 17 and the capacitor 19.

The greater the target voltage Vc is, the greater the impedance is, and therefore the greater the humidity level is.

The microcontroller 16 therefore compares the target voltage Vc with a predetermined threshold, and detects a humidity level which is too high on or in the printed circuit 1, between the first track 6a and the second track 6b, according to a result of said comparison. The microcontroller 16 detects a humidity level which is too high if the target voltage Vc is greater (in this case, strictly) than the predetermined threshold.

The predetermined threshold is, for example, equal to 200 mV.

The humidity detected can be present, either on the surface of the printed circuit 1 between the two tracks 6a, 6b, in the resin 12, or in the thickness of the printed circuit 3 (i.e. in the insulating material of the printed circuit).

It is noted that the absence of solder mask on the first track portion 8a and the second track portion 8b makes it possible to best capture the leak currents. However, this configuration is not necessary, and it is fully possible to leave all of the first and second tracks 6a, 6b covered with solder mask 7.

In the presence of humidity, leak currents of around 10 nA are measurable.

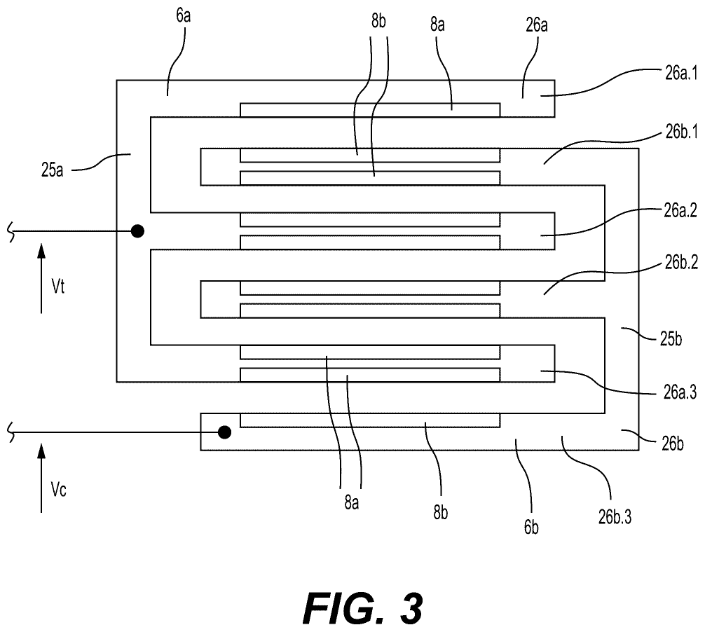

In reference to FIG. 3, in an alternative embodiment, the first track 6a and the second track 6b form two interdigitated electrodes.

The interdigitated electrodes are a particular electrode configuration widely used in electrochemical devices, such as gas sensors, pH sensors, glucose sensors, etc. An interdigitated electrode consists of a series of parallel metal electrodes disposed alternately and interconnected to distinct electrical regions. The interdigitated structure makes it possible to increase the length (and the surface area) of active electrode.

The first track 6a comprises, in this case, a first base 25a and three first fingers 26a perpendicular to the first base 25a. The second track 6a comprises, in this case, a second base 25b and three second fingers 26b perpendicular to the second base 25b.

The first fingers 26a and the second fingers 26b are disposed alternately by being parallel to one another.

Each first finger 26a comprises at least one first track portion 8a which is not covered with solder mask, and each second finger 26b comprises at least one second track portion 8b which is not covered with solder mask.

In this case, the first finger 26a.1 comprises one single first track portion 8a, while the first finger 26a.2 and the first finger 26a.3 each comprise two first track portions 8a.

Likewise, the second finger 26b.3 comprises one single second track portion 8b, while the second finger 26b.1 and the second finger 26b.2 each comprise two second track portions 8a.

The first track portions 8a and second track portions 8b are similar to those described above.

The test voltage Vt is applied on a central point of the first base 25a (at an end of the first central finger), optionally via one or more components, and the target voltage Vc is measured at an free end of the second finger of the bottom 26b (in the figure), optionally via one or more components.

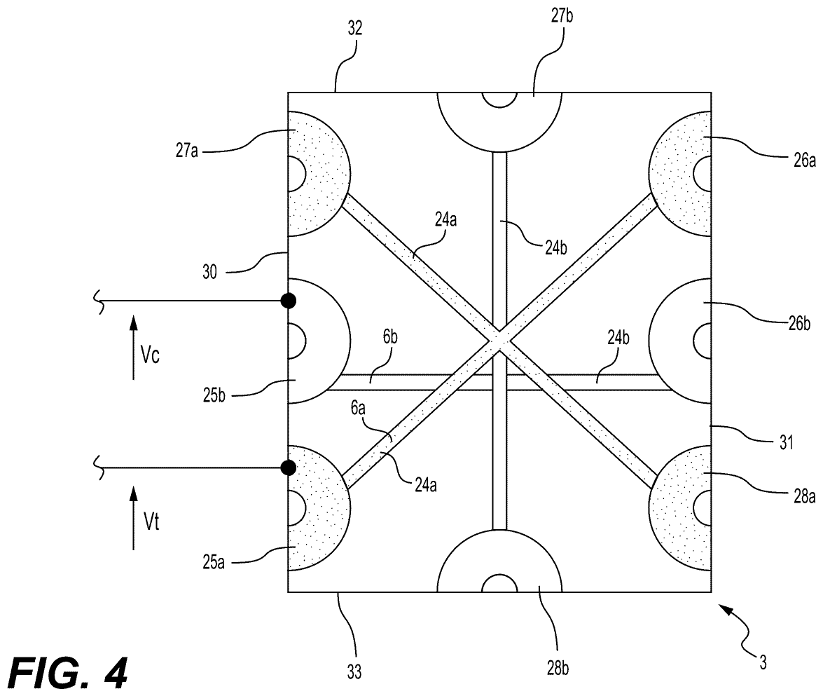

In reference to FIG. 4, in an alternative embodiment, the first track 6a and the second track 6b form electrodes arranged according to a castellation configuration.

The castellation is an electrode configuration used in semiconductive devices such as CMOS (complementary metal-oxide-semiconductor) technology chips or image sensors. It consists of a series of metal layers superposed with step- or notch-shaped openings, thus creating a stair structure. This configuration makes it possible to make vertical connections between different layers of integrated circuits, thus facilitating the integration and the interconnection of components.

The first track 6a is connected to at least one first castellation, formed in a thickness of the printed circuit 3.

The second track 6b is connected to at least one second castellation, formed in the thickness of the printed circuit.

The test voltage is applied on the first conductive track and the target voltage is measured on the second conductive track.

The first track 6a comprises, in this case, a first section 24a which connects two first castellations 25a, 26a to one another, and a first section 24b which connects two first castellations 27a, 28a to one another. The two first sections 24a are connected to one another and are, in this case, perpendicular to one another. The second track 6b comprises a second section 24b which connects two second castellations 25b, 26b to one another, and a second section 24b which connects two second castellations 27b, 28b to one another. The two second sections 24b are connected to one another and are, in this case, perpendicular to one another.

The second castellation 25b is positioned at a first edge 30 of the printed circuit 3 between the first castellation 25a and the first castellation 27a (in the middle). Likewise, the second castellation 26b is positioned at a first edge 31 (opposite the first edge) of the printed circuit 3 between the first castellation 26a and the first castellation 28a (in the middle).

The second castellation 27b is positioned in the middle of a third edge 32 (perpendicular to the first edge 30 and to the second edge 31), and the second castellation 28b is positioned in the middle of a fourth edge 33 (opposite to the third edge 32). The first sections 24a substantially form diagonals of the printed circuit 3.

The test voltage Vt is applied on the first castellation 25a (and therefore on the first track), optionally via one or more components, and the target voltage Vc is measured on the second castellation 25b (and therefore on the second track), optionally via one or more components.

The castellations are formed in the thickness of the printed circuit 3.

The castellations are formed, for example, by first making through vias (or PTH for plated through hole) in the printed circuit 3, then by cutting (by milling, for example) the printed circuit 3 so as to leave half of each through via in the section of the edge of the printed circuit.

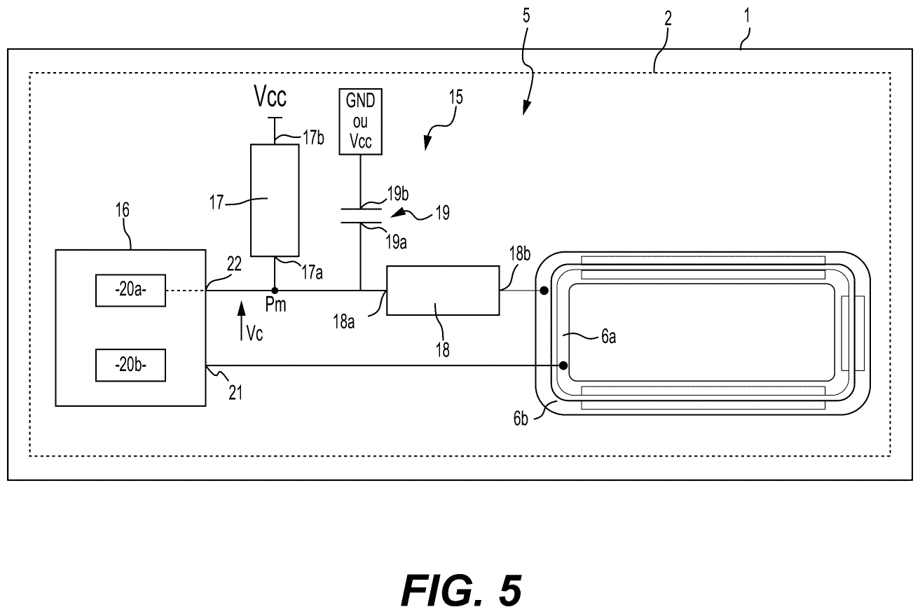

Now, in reference to FIG. 5, a second embodiment of the test device 15 is described.

The output 21 of the microcontroller 16 is directly connected to the first track 6a.

The input 22 of the microcontroller 16 (which is connected to the ADC 20a) is connected to the second track 6b via the resistor 17, the inductor (or the resistor) 18 and the capacitor 19.

The inductor (or the resistor) 18 has a terminal 18a connected to the input 22 and a terminal 18b connected to the second track 6b.

The capacitor 19 has a terminal 19a connected to the input 22 and to the terminal 18a of the inductor (or the resistor) 18, and a terminal 19b connected to the ground 23 (GND), to the supply (Vcc) or to any other voltage reference of the electronic board 2.

The resistor 17 has a terminal 17a connected to the input 22, to the terminal 18a of the inductor (or of the resistor) 18 and to the terminal 19a of the capacitor 19, and a terminal 17b connected to the supply Vcc.

The capacitor 19 and the resistor 17 are therefore mounted in parallel.

The activation of the device is done this time by bringing the first track 6a to the electrical ground (the CTRL signal of the microcontroller 16, which activates the measurement, is active at the ground).

The test voltage is therefore this time the voltage Vcc.

The target voltage Vc is measured at a measuring point Pm connected to the second track 6b by the inductor 18.

The microcontroller 16 detects a humidity level which is too high if the target voltage Vc is less than (in this case, less than or equal to) the predetermined threshold.

Again, the capacitor 19 and the inductor (or the resistor) 18 are optional.

Therefore, the electrical measurement has been inverted by referencing it to the supply, rather than to the ground.

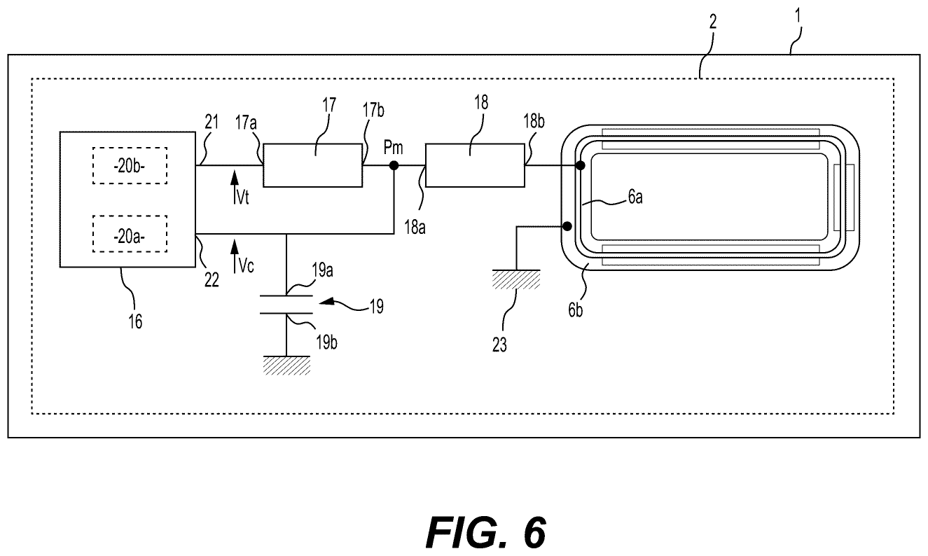

In reference to FIG. 6, a third embodiment of the test device 15 is now described.

This time, the output 21 of the microcontroller 16 is connected to the first track 6a via the resistor 17 and the inductor (or the resistor) 18, which are mounted in series. The terminal 17a of the resistor 17 is connected to the output 21. The terminal 17b of the resistor 17 is connected to the terminal 18a of the inductor (or the resistor) 18. The terminal 18b of the inductor (or the resistor) 18 is connected to the first track 6a.

The input 22 of the microcontroller 16 (which is connected to the ADC 20a) is connected to a measuring point Pm located between the terminal 17b of the resistor 17 and the terminal 18a of the inductor 18.

The terminal 19a of the capacitor is connected to the input 22 and to the measuring point Pm. The terminal 19b of the capacitor 19 is connected to the electrical ground 23.

The second track 6b is connected to the electrical ground 23.

The target voltage Vc is therefore measured at a measuring point Pm connected to the second track 6b by the inductor 18.

The microcontroller 16 detects a humidity level which is too high if the target voltage Vc is less than (in this case, less than or equal to) the predetermined threshold.

Again, the capacitor 19 and the inductor (or the resistor) 18 are optional.

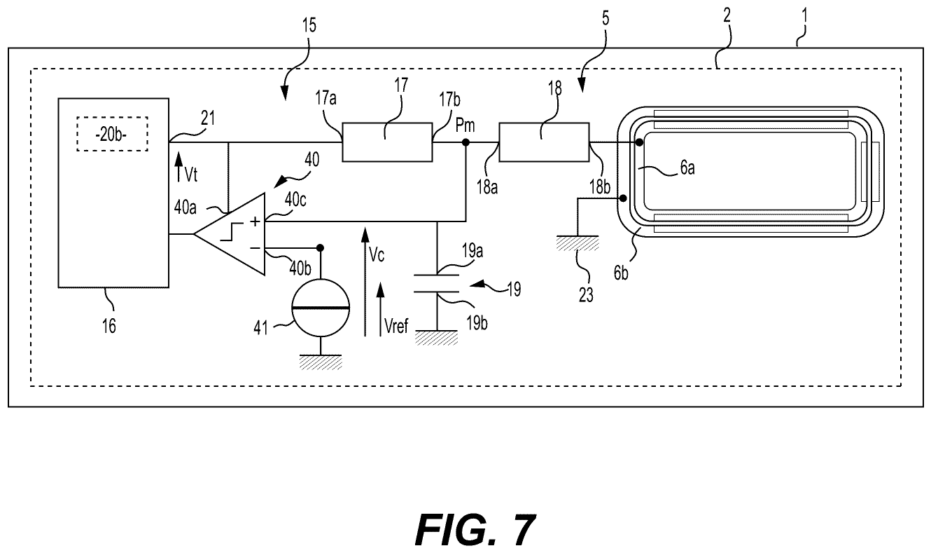

In reference to FIG. 7, a fourth embodiment of the test device 15 is now described.

The detection by the ADC is replaced by a detection by a comparator with threshold 40. The comparator is an analogue comparator.

The test device 15 this time comprises a voltage source 41 (generating a reference voltage Vref, in this case equal to 1.2V) and the comparator 40.

The output 21 of the microcontroller 16 is connected to the first track 6a via the resistor 17 and the inductor 18, which are therefore mounted in series. The terminal 17a of the resistor 17 is connected to the output 21. The terminal 17b of the resistor 17 is connected to the terminal 18a of the inductor 18. The terminal 18b of the inductor 18 is connected to the first track 6a.

The output 21 of the microcontroller 16 is also connected to a supply port 40a of the comparator 40 (which is therefore powered by the test voltage Vt).

The voltage source 41 is connected between the negative input 40b of the comparator 40 and the electrical ground 23, such that the reference voltage Vref is applied on this negative input 40b.

The terminal 19a of the capacitor 19 is connected to the positive input 40c of the comparator 40. The terminal 19b of the capacitor is connected to the ground 23.

The positive input 40c of the comparator 40 is connected to a measuring point Pm located between the resistor 17 and the inductor 18 (and therefore to the terminal 17b of the resistor 17, to the terminal 18a of the inductor 18 and to the terminal 19a of the capacitor 19).

The comparator 40 therefore compares the target voltage Vc with a reference voltage Vref produced by the reference source 41. When the target voltage Vc is less than the reference voltage Vref, the microcontroller 16 detects a humidity level which is too high.

The predetermined threshold, with which the target voltage is compared, is therefore, in this case, an analogue threshold.

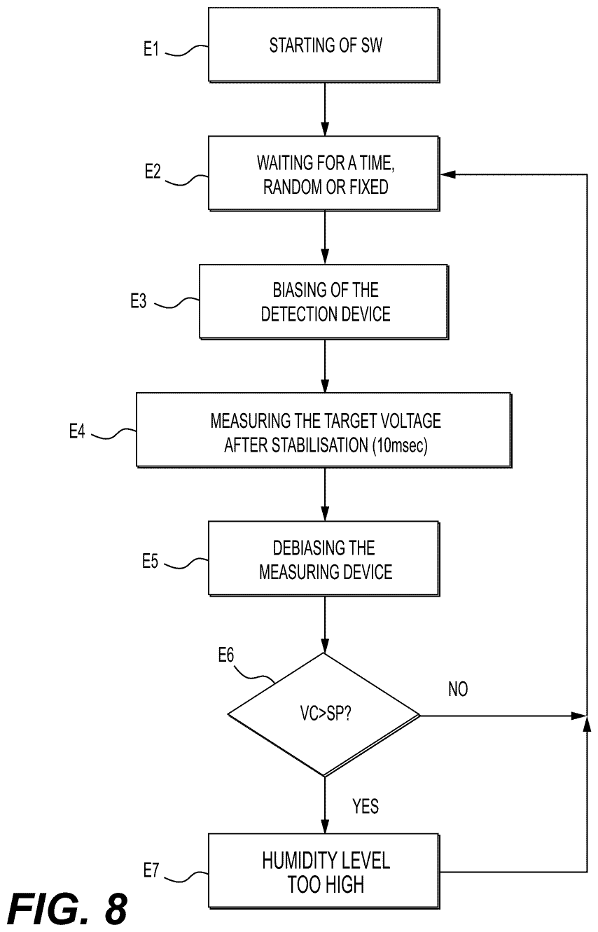

In reference to FIG. 8, a detection method is now described, which is, in this case, implemented by the microcontroller 16. The method is repeated periodically.

The microcontroller 16 starts the test software: step E1.

The microcontroller 16 waits for a waiting time. The waiting time has a predetermined duration (equal, for example, to 500s, or a random duration and picked at random (and possible comprised between a minimum terminal, equal, for example, to is, and a maximum terminal, equal, for example, to 1000s): step E2.

The microcontroller 16 applies the test voltage on the first track 6a and thus biases the monitoring device 5: step E3.

The microcontroller 16 waits for a certain duration that the target voltage Vc is stabilised (10 ms, typically), then measures the target voltage Vc: step E4.

The microcontroller thus depolarises the monitoring device 5: step E5.

The microcontroller 16 compares the target voltage Vc with the predetermined threshold Sp (200 mV, for example): step E6. It is noted that this predetermined threshold Sp can be configurable. The value of the threshold could, for example, be chosen according to the desired detection sensitivity.

The case is referred to, where the used test device 15 is that of FIG. 2.

If the target voltage Vc is less than (in this case, less than or equal to) the predetermined threshold, the method goes back to step E2.

If the target voltage is greater (in this case, strictly) than the predetermined threshold, the microcontroller 16 detects a humidity level which is too high: step E7.

If the used test device is that of FIG. 5, 6 or 7, the humidity level which is too high is detected when the target voltage is less than the predetermined threshold.

The microcontroller generates an alarm (or continues to generate it, if an alarm has already been generated) which alerts about a potential risk of reliability of the product. The microcontroller 16 counts the number of alarms already generated, by optionally associating each alarm with a timestamp.

This alarm, with or without its complementary information, can be displayed on the screen of the product 1 or be sent to the user and/or to the network manager and/or to the fluid dispenser if the meter is equipped with a communication module (LoRa, NB-IoT, W-Mbus, etc).

This alarm makes it possible for the user and/or for the network manager and/or for the fluid dispenser to take preventive measurements to ensure the durability and the correct operation of the meter.

The method goes back to step E2.

Numerous variants can be considered.

The printed circuit can comprise several first tracks connected in series, and several second tracks connected in series. Each assembly of a first track and of the associated second track is positioned in a distinct zone of the printed circuit. The humidity level which is too high is detected when the leak currents are present in several zones at the same time.

Likewise, the printed circuit can comprise several first tracks connected in parallel, and several second tracks connected in parallel.

The first track 6a and second track 6b can go along the edges of the printed circuit 3.

The first track and the second track can be printed on one same layer of the printed circuit (which can be an internal layer), or on two different layers. Thus, the humidity of the printed circuit is measured precisely in the thickness of it between the two layers.

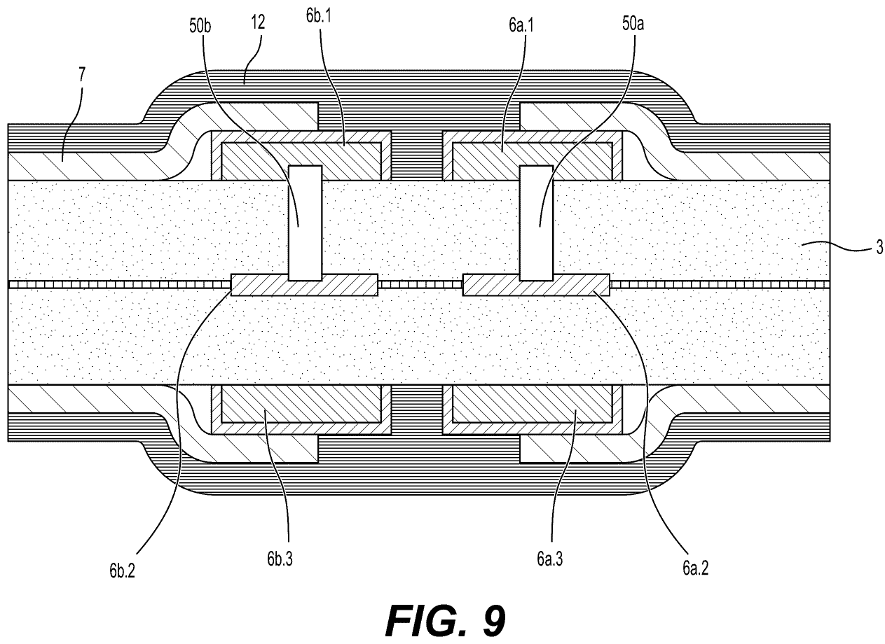

In reference to FIG. 9, it is also possible to have several first tracks on distinct layers and several second tracks on distinct layers.

In this case, two first tracks 6a.1, 6a.2 are provided, connected by at least one first through via 50a, the first track 6a.1 being located on an upper layer and the first track 6a.2 on an internal layer of the printed circuit 3. Also, a second track 6b.1 and a second track 6b.2 are provided, connected by at least one second through via 50b. Also, a first track 6a.3 and a second track 6b.3 is provided on the lower layer.

In the case where the electronic board comprises one or more components which are more sensitive than the others to humidity, this or these components can be positioned in a zone surrounded by the first track 6a and the second track 6b.

The components which are the most sensitive to humidity comprise, for example, an ASIC, a quartz, etc.

During the design of the electronic board, the component(s) which are the most sensitive to humidity will therefore start to be defined, then the first track and the second track are designed, such that they surround the zone in which this or these components are located. By “the most sensitive to humidity”, this means, for example, the components which have the greatest breakdown rate for a given humidity level.

The first track and/or the second track are not necessarily dedicated to detecting humidity.

The first track and/or the second track can be used, also for transporting any electrical signals (communication, control, supply, etc.) used for any other function.

Detecting the humidity level which is too high is done when said other function is inactive.

The invention has the following advantages.

Detecting humidity is effective, even in the presence of resin. Contrary to traditional humidity sensors (in particular, those integrated in a SMC box), the monitoring device effectively operates, even when the printed circuit is covered with resin or mask, thus offering a more reliable solution for detecting humidity on the electronic boards.

The monitoring device has a low energy consumption. It consumes clearly less current than traditional capacitive methods, which is particularly advantageous for low energy consumption applications (for example, fluid sensor equipped with cells).

Detecting humidity can be activated on demand; but it is also possible to leave the active function constantly, as the current leak is very low (and therefore, the consumption of the device is very low).

The monitoring device is very simple and has a reduced cost. It uses simple electrodes and DC (direct) impedance measurements for detecting humidity, which makes it less complex and less expensive than traditional SMC sensors.

These electrodes have an excellent adaptability. The shape of the electrodes used in this device for monitoring the humidity level based on the DC impedance measurement can be easily adapted for specifically targeting the zones of the printed circuit having an increased humidity risk. This adaptability enables a more precise detection and a better detection of the integrity of the critical zones of the electronic board.

The electrodes can be installed on a face, on the two faces of the printed circuit and optionally inside in an internal layer.

The placement and the surface area of the electrodes can be variable; the electrodes can be placed at the most exposed or the least exposed locations.

Measuring the leak current can be completed by filters (capacitor, inductor, common mode transformer) in order to reduce external interferences.

The opening of the solder mask makes it possible to measure humidity closest to the electrical conductors. It is not compulsory. Protecting copper conductors by a coating (gold-nickel type) is desired to avoid the oxidation of the conductors, but is not essential for the measuring function.

The monitoring device can be used on different types of electronic boards, of materials and of printed circuit configurations, thus offering a multipurpose solution for detecting humidity in various electronic applications.

The monitoring device is very sensitive. It is capable of detecting current leaks of around 10 nA in the presence of high humidity/condensation, offering a high sensitivity for detecting humidity on the electronic boards.

The monitoring device is less sensitive to interferences and to electromagnetic interferences than traditional SMC sensors, which makes it more robust and reliable in complex electronic environments.

Naturally, the invention is not limited to the embodiments described, but includes any variant entering into the scope of the invention such as defined by the claims.

As has been seen, the test device applies a test voltage on one of the first conductive track and second conductive track, the other of the first conductive track and second conductive track being connected to a constant or controlled voltage reference. The second track can thus be connected to an electrical ground, optionally via one or more components, but the constant or controlled voltage reference is not necessarily the 0V present on the ground. This can be, for example, a voltage obtained from a supply voltage, or produced by a voltage source.

The monitoring device is not necessarily implemented in a fluid meter, nor even in a meter, but can be integrated in any type of electrical equipment.

The processing component of the test device, wherein the detection method is implemented, is not necessarily a microcontroller. Another component could be considered, for example, a “general” processor, a processor specialising in processing the signal (or DSP, for digital signal processor), or a programmable logic circuit such as an FPGA (for field-programmable gate array) or an ASIC (for application-specific integrated circuit).

The processing component of the test device is not necessarily dedicated to monitoring humidity, it could be used for other functions (metrology, for example).

The comparator used could be a different comparator, for example, a Schmitt trigger.

1. A monitoring device for monitoring humidity on or in a printed circuit, comprising:
a first conductive track and a second conductive track printed on the printed circuit, and not connected to one another, the first conductive track comprising a first track portion which is not covered with solder mask, the rest of the first conductive track being covered with solder mask, and the second conductive track comprising a second track portion which is not covered with solder mask, the rest of the second conductive track being covered with solder mask; and
a test device arranged to:
apply a test voltage on one of the first conductive track and second conductive track, the other of the first conductive track and second conductive track being connected to a constant or controlled voltage reference;
compare a target voltage, representative of an impedance between the first conductive track and the second conductive track, with a predetermined threshold, said impedance being reduced in the presence of humidity; and
detect a humidity level which is too high on or in the printed circuit, between the first conductive track and the second conductive track, according to a result of said comparison.

2. The monitoring device according to claim 1, wherein the test voltage is a direct voltage.

3. The monitoring device according to claim 1, wherein the first track portion extends over a first segment of the first conductive track, and the second track portion extends over a second segment of the second conductive track, the first segment and the second segment going along over the printed circuit, being substantially parallel and being substantially of the same length.

4. The monitoring device according to claim 1, wherein the first track portion and the second track portion are covered with a protective coating intended to prevent a main material, with which the first conductive track and the second conductive track are manufactured, from corroding.

5. The monitoring device according to claim 4, wherein the protective coating is made of gold-nickel.

6. The monitoring device according to claim 1, wherein the first conductive track and the second conductive track form two loop-shaped electrodes.

7. The monitoring device according to claim 1, wherein the first conductive track and the second conductive track form two interdigitated electrodes.

8. The monitoring device according to claim 1, wherein:
the first conductive track is connected to at least one first castellation formed in a thickness of the printed circuit, and
the second conductive track is connected to at least one second castellation formed in the thickness of the printed circuit,
the test voltage is applied on the first conductive track and the target voltage being measured on the second conductive track.

9. The monitoring device according to claim 8, wherein the first conductive track comprises two first sections connected to one another, perpendicular to one another and each connecting two first castellations to one another, and the second conductive track comprises two second sections connected to one another, perpendicular to one another and each connecting two second castellations to one another.

10. The monitoring device according to claim 1, wherein the first conductive track and the second conductive track are located on one same layer of the printed circuit.

11. The monitoring device according to claim 10, wherein said layer is an internal layer of the printed circuit.

12. The monitoring device according to claim 1, further comprising a first conductive track and a second conductive track located on a first layer of the printed circuit, and another first conductive track and another second conductive track located on a second layer of the printed circuit, the first conductive tracks being connected to one another by at least one first through via and the second conductive being connected to one another by at least one second through via.

13. The monitoring device according to claim 1, comprising several first conductive tracks connected in series and several second conductive tracks connected in series.

14. The monitoring device according to claim 1, further comprising several first conductive tracks connected in parallel and several second conductive tracks connected in parallel.

15. The monitoring device according to claim 1, wherein the first conductive track and/or the second conductive track are arranged for transporting signals used for another function, the monitoring device being arranged to perform the detection of the humidity level which is too high when said other function is inactive.

16. The monitoring device according to claim 1, wherein electrical components are mounted on the printed circuit, these electrical components comprising a component which is the most sensitive to humidity, the component which is the most sensitive to humidity being positioned in a zone surrounded by the first conductive track and the second conductive track.

17. The monitoring device according to claim 1, further comprising an analogue comparator and a voltage source, the target voltage being compared by the analogue comparator with a reference voltage produced by the voltage source, the predetermined threshold thus being an analogue threshold.

18. A detection method, implemented in a monitoring device according to claim 1, comprising the steps of:
applying a test voltage on one of the first conductive track and second conductive track, the other of the first conductive track and second conductive track being connected to a constant or controlled voltage reference;
comparing a target voltage, representative of an impedance between the first conductive track and the second conductive track, with a predetermined threshold, said impedance being reduced in the presence of humidity; and
detecting a humidity level which is too high on or in the printed circuit, between the first conductive track and the second conductive track, according to a result of said comparison.

19. (canceled)

20. A non-transitory computer-readable recording medium, on which a computer program comprising instructions which cause a test device of a monitoring device to execute the steps of the detection method according to claim 18 is recorded.
